(19) United States
(12) Patent Application Publication
(10) Pub. No.: US 2025/0008693 A1
(43) Pub. Date: Jan. 2, 2025

(54) DUAL-PHASE FLUID HEAT-DISSIPATING ELEMENT AND PRODUCT HAVING THE SAME

(71) Applicants: TZU-CHIA TAN, TAOYUAN CITY (TW); YAO-CHUN WANG, TAOYUAN CITY (TW); EVERBRITE TECHNOLOGY CO., LTD., TAOYUAN CITY (TW)

(72) Inventors: Tzu-Chia TAN, TAOYUAN CITY (TW); YAO-CHUN WANG, TAOYUAN CITY (TW); WEN-HUNG LIN, TAOYUAN CITY (TW); WEN-YUAN CHOU, TAOYUAN CITY (TW); PO-CHING LIN, TAOYUAN CITY (TW); SHANTI KARTIKA SARI, TAOYUAN CITY (TW)

(21) Appl. No.: 18/755,879

(22) Filed: Jun. 27, 2024

(30) Foreign Application Priority Data
Jun. 29, 2023 (TW) 112206700

(51) Int. Cl. H05K 7/20

(52) U.S. Cl. CPC H05K 7/20336; H05K 7/20327

(57) ABSTRACT

A heat-dissipating element having a casing having a closed fluid space. At least a part of the fluid space is filled with a coolant fluid, and the coolant fluid is transformed between a liquid phase and a gas phase by an environment temperature transferred by the casing.

### FIELD OF INVENTION

The present invention relates to a heat-dissipating element, particularly to a dual-phase fluid heat-dissipating element and a product having the same.

### BACKGROUND OF THE INVENTION

With the improvement of technology, electronic products are widely used in human live. For use in convenience, the electronic products gradually have multi-functions designs. Because the temperature of an electronic product will be increased during the operation of the electronic product, a heat-dissipating assembly, such as fans, fan-motor or heat-dissipating holes is usually disposed on the electronic product to assist the temperature of the electronic product to cool down. Thus, the electronic product can be kept from being damaged by high temperature and can be prevented the useful life of the electronic product from being shorten.

However, to increase the heat-dissipating effect, the number of the dissipating assembly disposed on an electronic product will be increased. Thus, the miniaturized design of an electronic product will be limited. In addition, fans or fan-motors will generate noise during the operation of the fans or fan-motors, and heat is also generated during the operation of the fans or fan-motors. Therefore, a heat-dissipating element that can assist to dissipate heat, keep temperature from being increased, assist to miniaturize the volume of an electronic product is needed.

To overcome the shortcomings, the present invention tends to provide a heat-dissipating element to mitigate and/or obviate the aforementioned problems.

### SUMMARY OF THE INVENTION

For assisting to dissipate heat, keeping temperature from being increased, assisting to miniaturize the volume of an electronic product, the present invention provides a heat-dissipating element having a casing having a closed fluid space. At least a part of the fluid space is filled with a coolant fluid, and the coolant fluid is transformed between a liquid phase and a gas phase by an environment temperature transferred by the casing.

When the dual-phase fluid heat-dissipating element in accordance with the present invention is in use and the environment temperature is increased, the coolant fluid can absorb heat of the environment temperature and is transformed to a gas phase to keep the environment temperature at a desired level. When the environment temperature is decreased, the coolant fluid can release heat to be transformed to a liquid phase. Accordingly, when the dual-phase fluid heat-dissipating element is applied to a cell phone, a computer, a home appliance, or a precision instrument, the environment temperature of the electronic product can be kept at a stable range to prevent components of the electronic product from being damaged by a high temperature or a low temperature, such that the operation quality of the electronic product can be kept at a stable condition.

The dual-phase fluid heat-dissipating element in accordance with the present invention has a simple structure, is easily manufactured, and has a reduced manufacturing cost. Compare to the conventional heat-dissipating assembly applied to an electronic product and having complicated components, such as fans or fan-motors, the dual-phase fluid heat-dissipating element can maintain the heat-dissipating effect and largely miniaturizes the volume of an electronic product to achieve the objective of miniaturizing the volume of an electronic product.

The dual-phase fluid heat-dissipating element in accordance with the present invention can be applied to wide fields and is detachably combined with an electronic product. Thus, the electronic product can reduce or omit some components of a heat-dissipating assembly based on demands. The conventional heat-dissipating assembly can be changed by the dual-phase fluid heat-dissipating element in accordance with the present invention, the dual-phase fluid heat-dissipating element in accordance with the present invention can be made as a module to reduce the manufacturing cost.

### BRIEF DESCRIPTION OF THE DRAWINGS

FIG. 1 is a perspective view of a first embodiment of a heat-dissipating in accordance with the present invention;

FIG. 2 is an enlarged cross sectional side view of the heat-dissipating element in FIG. 1;

FIG. 3 is a perspective view of a second embodiment of a heat-dissipating in accordance with the present invention; and

FIG. 4 is an exploded perspective view of a third embodiment of a heat-dissipating in accordance with the present invention.

### DETAILED DESCRIPTION OF THE PREFERRED EMBODIMENTS

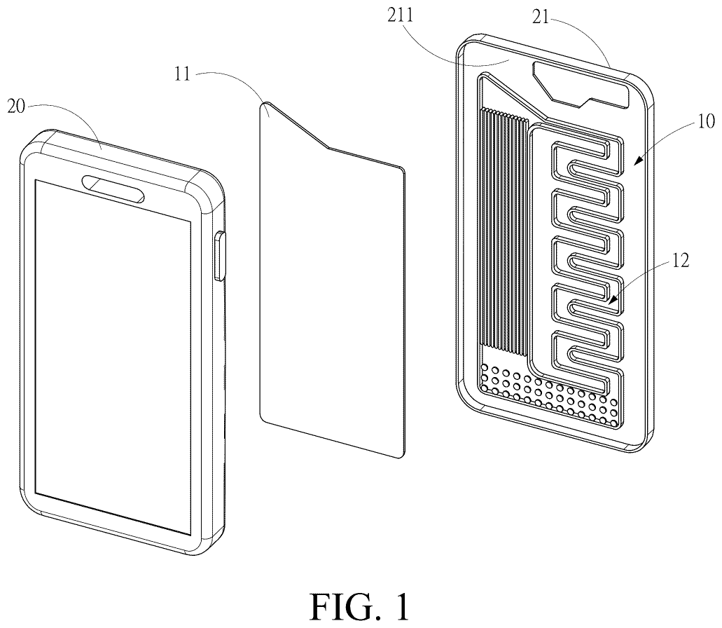

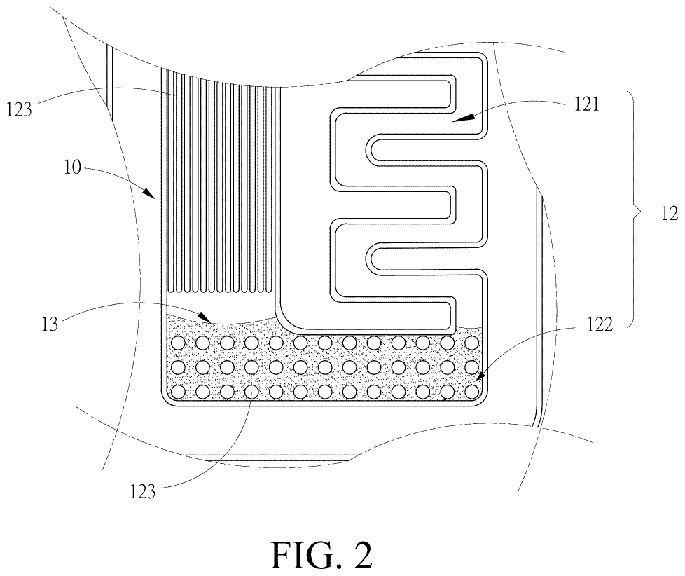

With reference to FIG. 1 and FIG. 2, a heat-dissipating element 10 in accordance with the present invention comprises a casing 11. The casing 11 is made of a heat-conductive material and has a fluid space 12 defined in the casing 11. The fluid space 12 is a closed space and at least a part of the fluid 12 is filled with a coolant fluid 13. The casing 11 can transfer an environment temperature into the fluid space 12, such that the coolant fluid 13 can be transformed between a liquid phase and a gas phase by an environment temperature.

Wherein, the heat-conductive material may be plastic material having a high thermal conductivity or metal, and the heat-conductive material may be copper, aluminum or a complex thereof.

Wherein, with increase of the environment temperature, the ratio of the gas phase of the coolant fluid 13 is increased.

Wherein, after or before the fluid space 12 is filled with the coolant fluid 13, the fluid space 12 is in a vacuum environment or a negative pressure environment by a vacuuming process. This is means that when the coolant fluid 13 is all 11 in the liquid phase, the fluid space 12 in a vacuum environment or a negative pressure environment.

Wherein, when the coolant fluid 13 is all in the liquid phase, the volume of the coolant fluid 13 in the liquid phase is smaller than the volume of the fluid space 12.

Furthermore, the coolant fluid 13 may be a liquid with a high volatility, such as water, alcohols, alkanes, or fluorinert liquid.

When the dual-phase fluid heat-dissipating element 10 is in use and the environment temperature is increased, the coolant fluid 13 can absorb heat of the environment temperature and is transformed to a gas phase to keep the environment temperature at a desired level. When the environment temperature is decreased, the coolant fluid 13 can release heat to be transformed to a liquid phase to keep the environment temperature at the desired level. Accordingly, when the dual-phase fluid heat-dissipating element 10 is applied to an electronic product 20, such as a cell phone, a computer, a home appliance, or a precision instrument, the environment temperature of the electronic product 20 can be kept at a stable range to prevent components of the electronic product from being damaged by a high temperature or a low temperature, such that the operation quality of the electronic product 20 can be kept at a stable condition.

Preferably, the heat-conduct material is a non-metal material, such that signal shielding caused by the combination use of the dual-phase fluid heat-dissipating element with an electronic product 20 with a communication function can be prevented, and a light weight effect can be also provided.

In addition, the fluid space 12 includes a gas-storage segment 121 and a liquid-storage segment 122. The gas-storage segment 121 is applied to hold the coolant fluid 13 in the gas phase inside, and the liquid-storage segment 122 is applied to hold the coolant fluid 13 in the liquid phase inside. When the dual-phase fluid heat-dissipating element 10 is in use, the gas-storage segment 121 has a horizontal position higher than a horizontal position of the liquid-storage segment. 122. accordingly, the coolant fluid 13 in the liquid phase can be isolated from the coolant fluid 13 in the gas phase in the fluid space 12 to keep the coolant fluid 13 in the gas phase in a bubble form stay in the coolant fluid 13 in the liquid phase and to prevent a bad influence to the transfer of the environment temperature.

Wherein, a guiding structure 123 is formed on an inner surface of the casing 11 at a position corresponding to the liquid-storage segment 12 and protruding toward the gas-storage segment 121. Accordingly, when the coolant fluid 13 in the gas phase is transformed to the liquid phase, the coolant fluid 13 in the liquid phase can be condensed on surfaces of the guiding structure 123 in the gas-storage segment 121 and flow into the liquid-storage segment 122 via the guiding structure 123.

Wherein, the form of the guiding structure 123 is not limited in the present invention, the guiding structure 123 may be ribs in stub form, rods in a long strip form, or a block form.

Furthermore, the guiding structure 123 is rods in a long strip form, and two ends of the guiding structure 123 extend toward the gas-storage segment 121 and the liquid-storage segment 122 respectively.

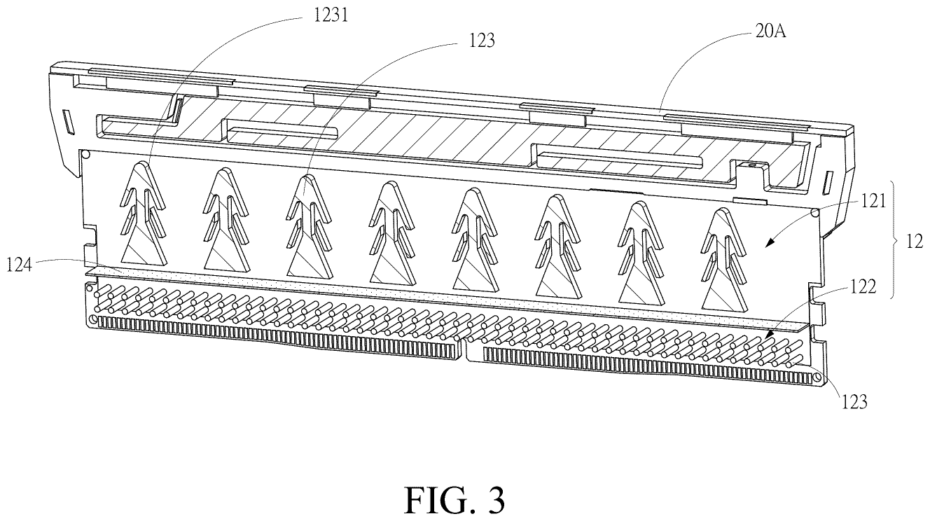

In addition, with reference to FIG. 3, the guiding structures 123 is a block having an inclined surface 1231 formed on a side of the block connected with the casing 11.

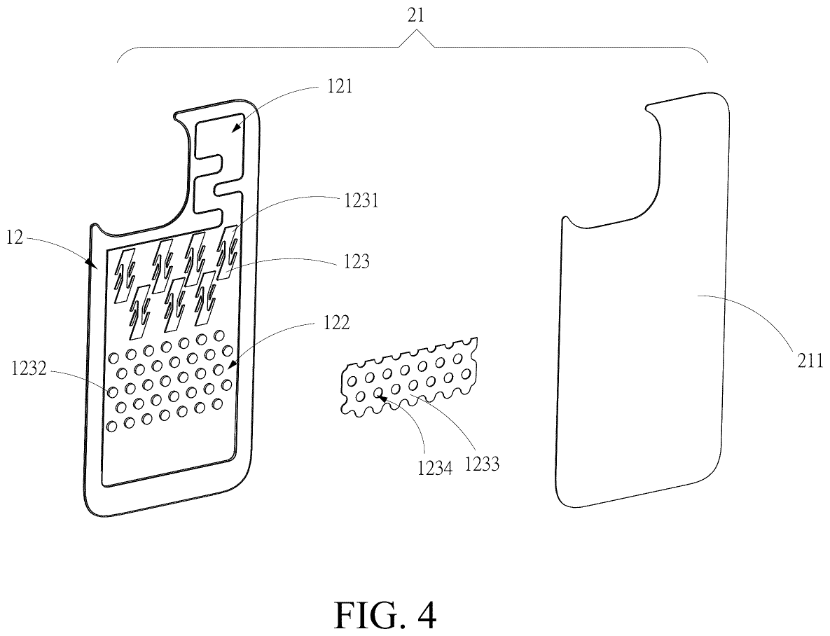

Furthermore, with reference to FIG. 4, the guiding structure 123 comprises at least one rib 1232 in a stub form and a capillary guiding sheet 1233. The capillary guiding sheet 1233 comprises a holding hole 1234 into which rib 1232 extends. Accordingly, the rib 1232 has a guiding effect and can hold the capillary guiding sheet 1233 in position. The capillary guiding sheet 1233 has a capillary structure to make the coolant fluid 13 be evenly distributed in the liquid-storage segment 122 by the capillary.

Wherein, at least a part of the capillary guiding sheet 1233 is in contact with the coolant fluid 13 in the liquid phase and/or the other part of the capillary guiding sheet 1233 is in in contact with the coolant fluid 13 in the gas phase.

Wherein, the capillary guiding sheet 1233 is distributed in the fluid space 12 or is disposed at a position corresponding to heat zone of an electronic product 20 to guide the coolant fluid 13 in the gas phase to be distributed.

Wherein, a unidirectional filter film 124 is disposed between the gas-storage segment 121 and the liquid-storage segment 122. The unidirectional filter film 124 can make the coolant fluid 13 in the gas phase and the coolant fluid 13 in the liquid phase respectively flow to the gas-storage segment 121 and the liquid-storage segment 122 to isolate the coolant fluid 13 in the gas phase and the liquid phase from each other.

The dual-phase fluid heat-dissipating element 10 in accordance with the present invention has a simple structure, is easily manufactured, and has a reduced manufacturing cost. Compare to the conventional heat-dissipating assembly applied to an electronic product 20 and having complicated components, such as fans or fan-motors, the dual-phase fluid heat-dissipating element 10 can maintain the heat-dissipating effect and largely miniaturizes the volume of an electronic product 20 to achieve the objective of miniaturizing the volume of an electronic product 20.

The dual-phase fluid heat-dissipating element 10 in accordance with the present invention can be applied to wide fields and is detachably combined with an electronic product 20. Thus, the electronic product 20 can reduce or omit some components of a heat-dissipating assembly based on demands. The conventional heat-dissipating assembly can be changed by the dual-phase fluid heat-dissipating element 10 in accordance with the present invention, the dual-phase fluid heat-dissipating element 10 in accordance with the present invention can be made as a module to reduce the manufacturing cost.

In another embodiment, the dual-phase fluid heat-dissipating element 10 is mounted on an inner surface 211 of a cellphone case 21. When the inner surface 211 of the cellphone case 21 faces to the electronic product 20 (the cellphone), the dual-phase fluid heat-dissipating element 10 can be directly in contact with the electronic product 20 to provide a heat-dissipating effect to the electronic product 20.

Wherein, the dual-phase fluid heat-dissipating element 10 can be at least a part of the inner surface 211 of the cellphone case 21.

With reference to FIG. 3, in another embodiment, the dual-phase fluid heat-dissipating element 10 is combined with a computer memory card 20A. The dual-phase fluid heat-dissipating element 10 is mounted on a side of the computer memory card 20A and is in contact with an inner environment of the computer memory card 20A via the casing 11. When the computer memory card 20A is mounted in a computer, the horizontal position of the gas-storage segment 121 of the fluid space 12 is higher than the horizontal position of the liquid-storage segment 122. The arrangement of the gas-storage segment 121 and the liquid-storage segment 122 can assist to maintain the transformation efficient of the coolant fluid 13 and to increase the temperature-sensitive of the dual-phase fluid heat-dissipating element 10 to the environment temperature.

What is claimed is:

1. A heat-dissipating element comprising:
a casing comprising a closed fluid space defined in the casing, wherein
at least a part of the fluid space is filled with a coolant fluid, the coolant fluid is transformed between a liquid phase and a gas phase by an environment temperature transferred by the casing.

2. The heat-dissipating element as claimed in claim 1, wherein when the coolant fluid is all in the liquid phase, the fluid space is in a vacuum environment or a negative pressure environment.

3. The heat-dissipating element as claimed in claim 1, wherein the fluid space includes a gas-storage segment and a liquid-storage segment, and the gas-storage segment has a horizontal position higher than a horizontal position of the liquid-storage segment.

4. The heat-dissipating element as claimed in claim 3, wherein a guiding structure formed on an inner surface of the casing at a position corresponding to the liquid-storage segment and protruding toward the gas-storage segment.

5. The heat-dissipating element as claimed in claim 4, wherein the guiding structure has two ends extending toward the gas-storage segment and the liquid-storage segment respectively.

6. The heat-dissipating element as claimed in claim 4, wherein the guiding structure has an inclined surface.

7. The heat-dissipating element as claimed in claim 4, wherein the guiding structure comprises a capillary guiding sheet having a capillary structure and has at least a part being in contact with the coolant fluid in the liquid phase.

8. The heat-dissipating element as claimed in claim 4, wherein the guiding structure comprises a capillary guiding sheet having a capillary structure and has at least a part being in contact with the coolant fluid in the gas phase.

9. The heat-dissipating element as claimed in claim 3, wherein a unidirectional filter film is disposed between the gas-storage segment and the liquid-storage segment.

10. The heat-dissipating element as claimed in claim 1, wherein the coolant fluid is water, alcohols, alkanes, or fluorinert liquid.

11. A product comprising
a casing attached to at least a part of surface of an electronic product and comprising a closed fluid space defined in the casing, wherein
at least a part of the fluid space is filled with a coolant fluid, the coolant fluid is transformed between a liquid phase and a gas phase by an environment temperature transferred by the casing.

12. The product as claimed in claim 11, wherein when the coolant fluid is all in the liquid phase, the fluid space is in a vacuum environment or a negative pressure environment.

13. The product as claimed in claim 11, wherein the fluid space includes a gas-storage segment and a liquid-storage segment, and the gas-storage segment has a horizontal position higher than a horizontal position of the liquid-storage segment.

14. The product as claimed in claim 13, wherein a guiding structure formed on an inner surface of the casing at a position corresponding to the liquid-storage segment and protruding toward the gas-storage segment.

15. The product as claimed in claim 14, wherein the guiding structure has two ends extending toward the gas-storage segment and the liquid-storage segment respectively.

16. A product being a computer memory card and comprising a casing comprising a closed fluid space defined in the casing, wherein
at least a part of the fluid space is filled with a coolant fluid, the coolant fluid is transformed between a liquid phase and a gas phase by an environment temperature transferred by the casing.

17. The product as claimed in claim 16, wherein when the coolant fluid is all in the liquid phase, the fluid space is in a vacuum environment or a negative pressure environment.

18. The product as claimed in claim 15, wherein the fluid space includes a gas-storage segment and a liquid-storage segment, and the gas-storage segment has a horizontal position higher than a horizontal position of the liquid-storage segment.

19. The product as claimed in claim 17, wherein a guiding structure formed on an inner surface of the casing at a position corresponding to the liquid-storage segment and protruding toward the gas-storage segment.

20. The product as claimed in claim 17, wherein the guiding structure comprises a capillary guiding sheet.
